(19) United States
(12) Patent Application Publication
(10) Pub. No.: US 2025/0385655 A1
(43) Pub. Date: Dec. 18, 2025

(54) PLATE MODE MICROACOUSTIC FILTERS INCLUDING BILATERAL TEMPERATURE COEFFICIENT OF FREQUENCY (TCF) LAYERS

(71) Applicant: RF360 Singapore Pte. Ltd., Singapore (SG)

(72) Inventors: Soeren Zimmermann, München (DE); Marc Konstantin Dietrich, Munich (DE)

(21) Appl. No.: 18/741,978

(22) Filed: Jun. 13, 2024

(51) Int. Cl. H03H 3/04; H03H 9/54

(52) U.S. Cl. CPC H03H 9/02448; H03H 3/04

(57) ABSTRACT

A temperature coefficient of frequency (TCF) compensation layer may be disposed on a second surface of a piezoelectric layer opposite to a first surface to reduce the TCF of a microacoustic filter. The frequency response of a microacoustic filter with the TCF compensation layer on only the second surface of the piezoelectric layer includes spurious modes. In an exemplary microacoustic filter, another TCF compensation layer is disposed on the first surface of the piezoelectric layer between the electrode structure and the piezoelectric layer. Providing TCF compensation layers bilaterally on the first and second surfaces of the piezoelectric layer reduces spurious modes in the frequency response of the microacoustic filter. In some examples, the electrode structure is disposed on a substrate and may be isolated from the TCF compensation layer on the first surface of the piezoelectric layer by an air gap to reduce acoustic losses.

### TECHNICAL FIELD

The technology of the disclosure relates generally to wireless transceivers and other components that employ acoustic filters and, more specifically, to microacoustic filters employing plate mode resonators.

### BACKGROUND

Electronic devices may use radio-frequency (RF) signals to communicate information that enables voice communication, uploading and downloading of media (e.g., audio and video), remote control of household devices, and reception of global positioning information, for example. To transmit or receive the radio-frequency signals within a given frequency band allocated for such communications, the electronic device may use filters that pass signals within the frequency band and suppress (e.g., attenuate) jammers or noise having frequencies outside of the frequency band. It can be challenging, however, to design and manufacture a filter that provides filtering for radio-frequency applications, especially those that operate at frequencies above 2 gigahertz (GHz).

### SUMMARY

Aspects disclosed in the detailed description include plate mode microacoustic filters including bilateral temperature coefficient of frequency (TCF) layers. Methods of making such microacoustic filters, including bilateral TCF layers, are also disclosed. The crystalline structure of a piezoelectric layer in a microacoustic filter may be laterally excited to operate in a plate mode in response to electric fields produced by a voltage in an electrode structure disposed adjacent to a first surface of the piezoelectric layer. A TCF compensation layer may be disposed on a second surface of the piezoelectric layer opposite to the first surface to reduce the TCF of the microacoustic filter. A TCF compensation layer disposed on the piezoelectric layer prevents or reduces changes in operating frequency with temperature. The frequency response of a microacoustic filter with the TCF compensation layer on only the second surface of the piezoelectric layer includes spurious modes. In an exemplary microacoustic filter, another TCF compensation layer is disposed on the first surface of the piezoelectric layer between the electrode structure and the piezoelectric layer. Providing TCF compensation layers bilaterally on the first and second surfaces of the piezoelectric layer reduces spurious modes in the frequency response of the microacoustic filter. In some examples, the electrode structure is disposed on a substrate and may be isolated from the TCF compensation layer on the first surface of the piezoelectric layer by an air gap to reduce acoustic losses.

In this regard in one aspect, a microacoustic filter is disclosed. The microacoustic filter includes a piezoelectric layer having a crystalline structure operative to laterally excite a plate mode, an electrode structure disposed on a first surface of the piezoelectric layer, a first TCF compensation layer disposed on the first surface of the piezoelectric layer between the electrode structure and the piezoelectric layer and a second TCF compensation layer disposed on a second surface of the piezoelectric layer opposite to the first surface.

In another aspect, a method of manufacturing a microacoustic filter is disclosed. The method includes forming a piezoelectric layer having a crystalline structure operative to laterally excite a plate mode, forming a first TCF compensation layer on a first surface of the piezoelectric layer, forming a second TCF compensation layer on a second surface of the piezoelectric layer opposite to the first surface, and forming an electrode structure opposite to the first surface of the piezoelectric layer.

### BRIEF DESCRIPTION OF THE DRAWINGS

FIG. 1 illustrates an example operating environment for operating a microacoustic filter with bilateral temperature coefficient of frequency (TCF) compensation layers on the piezoelectric layer;

FIG. 2 illustrates an example wireless transceiver including at least one microacoustic filter with bilateral TCF compensation layers on the piezoelectric layer;

FIG. 3-1 illustrates example components of a microacoustic filter with bilateral TCF compensation layers on the piezoelectric layer;

FIG. 3-2 illustrates example Euler angles that define an orientation of a piezoelectric layer of a microacoustic filter with bilateral TCF compensation layers on the piezoelectric layer;

FIG. 4A is a perspective view of one example of a microacoustic filter configured to operate in a plate mode and including TCF compensation layers disposed bilaterally on the piezoelectric layer;

FIG. 4B is a cross-sectional side view of the microacoustic filter in FIG. 4A illustrating electric field lines of an electric field induced in the piezoelectric layer by an electrode structure;

FIG. 4C is a graph of the frequency response of the microacoustic filter shown in FIG. 4A;

FIG. 4D is a graph of frequency responses of a microacoustic filter as shown in FIG. 4A but having various layer thicknesses of the first TCF compensation layer, to illustrate a shift in resonant frequencies corresponding to the TCF compensation layer thickness;

FIG. 5 is a flow chart of a method of making the microacoustic filter in FIGS. 4A and 4B;

FIG. 6A is a cross-sectional side view of a microacoustic filter configured to operate in a plate mode and employing a TCF compensation layer on only an upper side of the piezoelectric layer;

FIG. 6B is a graph of the frequency response of the microacoustic filter shown in FIG. 5A;

FIG. 7 is a cross-sectional side view of a microacoustic filter as shown in FIG. 4B, additionally including passivation layers formed on each of the TCF compensation layers;

FIG. 8 is a block diagram of an exemplary processor-based system that can include microacoustic filters in which TCF compensation layers are disposed bilaterally on the piezoelectric layer; and

FIG. 9 is a block diagram of an exemplary wireless communication device that includes radio-frequency (RF) components that can include microacoustic filters, including bilateral TCF compensation layers on a piezoelectric layer that is laterally excited to operate in a plate mode.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include plate mode microacoustic filters including bilateral temperature coefficient of frequency (TCF) layers. Methods of making microacoustic filters including bilateral TCF layers are also disclosed. The crystalline structure of a piezoelectric layer in a microacoustic filter may be laterally excited to operate in a plate mode in response to electric fields produced by a voltage in an electrode structure disposed adjacent to a first surface of the piezoelectric layer. A TCF compensation layer may be disposed on a second surface of the piezoelectric layer opposite to the first surface to reduce the TCF of the microacoustic filter. A TCF compensation layer disposed on the piezoelectric layer prevents or reduces changes in operating frequency with temperature. The frequency response of a microacoustic filter with the TCF compensation layer on only the second surface of the piezoelectric layer includes spurious modes. In an exemplary microacoustic filter, another TCF compensation layer is disposed on the first surface of the piezoelectric layer between the electrode structure and the piezoelectric layer. Providing TCF compensation layers bilaterally on the first and second surfaces of the piezoelectric layer reduces spurious modes in the frequency response of the microacoustic filter. In some examples, the electrode structure is disposed on a substrate and may be isolated from the TCF compensation layer on the first surface of the piezoelectric layer by an air gap to reduce acoustic losses.

To transmit or receive radio-frequency signals within a given frequency band, an electronic device may use filters to pass signals within the frequency band and to suppress (e.g., attenuate) jammers or noise-having frequencies outside of the frequency band. Electroacoustic devices (e.g., “acoustic filters”) can be used to filter high-frequency signals in many applications, such as those with frequencies that are greater than 100 megahertz (MHz). An acoustic filter is tuned to pass certain frequencies (e.g., frequencies within its passband) and attenuate other frequencies (e.g., frequencies that are outside of its passband). In an acoustic resonator or an acoustic filter, an electrical signal having a time-varying voltage is applied to an electrode structure to create an electric field of varying intensity in a piezoelectric material. The piezoelectric material transforms the varying electric field into an acoustic wave. The acoustic wave induces an electric field in the piezoelectric material and the electrode structure detects the electric field and transforms or converts it to an electrical output signal.

The resonant frequencies of acoustic resonators are determined by dimensions of the acoustic resonator and/or electrode structure. Since higher frequency signals have shorter wave lengths, smaller dimensions are needed. Accordingly, such frequencies can make it challenging to design a microacoustic filter that can provide filtering for signals at higher frequencies, such as those used with Wi-Fi® at 2.4 gigahertz (GHz) frequencies, at 5 GHz frequencies, at frequencies greater than 5 GHz, at sub-6 GHz frequencies, at frequencies between 6 and 18 GHz, and/or at frequencies greater than or equal to 10 GHz. In particular, it can be challenging to design a filter that is affordable and can realize a target level of performance in terms of resonance quality factors, electromechanical coupling, power durability, insertion loss, and spurious-mode suppression.

To address these challenges, some microacoustic filters implement a laterally-excited plate-mode in the piezoelectric layer. The laterally-excited plate-mode microacoustic filter can realize a target level of performance in terms of electromechanical coupling, insertion loss, and quality factors at the higher frequencies. Performance of these filters, however, can be negatively impacted by a rate of change of frequency with a change in temperature, known as temperature coefficient of frequency (TCF). To address this issue, a TCF compensation layer has been formed on a surface of the piezoelectric layer on the side opposite to that of the electrode structure. The TCF compensation layer may have a low coefficient of thermal expansion (CTE) and a positive coefficient of elasticity, such that having the TCF compensation layer disposed on the piezoelectric layer will influence the phase velocity of the acoustic wave and reduces or avoids changes in operating frequency.

To provide performance improvements in this regard, microacoustic filters including bilateral TCF compensation layers on the piezoelectric layer are disclosed. In addition to a first TCF compensation layer disposed on a first surface of the piezoelectric layer on a side opposite to the electrode structure, a second TCF compensation layer is formed on a second surface of the piezoelectric layer on a same side as the electrode structure. In an acoustic resonator employing a laterally-excited plate mode in the piezoelectric layer, the second TCF compensation layer can be formed between the electrode structure and the piezoelectric layer and may be formed directly on the piezoelectric layer. Having bilateral TCF compensation layers further restricts change of phase velocity upon temperature variation compared to a single TCF compensation layer, and also avoids distortion of the acoustic wave in the piezoelectric layer caused by the TCF compensation layer on only one side, in turn improving performance of the acoustic resonance. The bilateral TCF compensation layers reduce the TCF of the acoustic resonator compared to acoustic resonators with a single TCF compensation layer. As such, the microacoustic filter can realize significantly reduced TCF, improved spurious-mode suppression, and improved quality factor compared to other microacoustic filters, without significantly affecting electromechanical coupling.

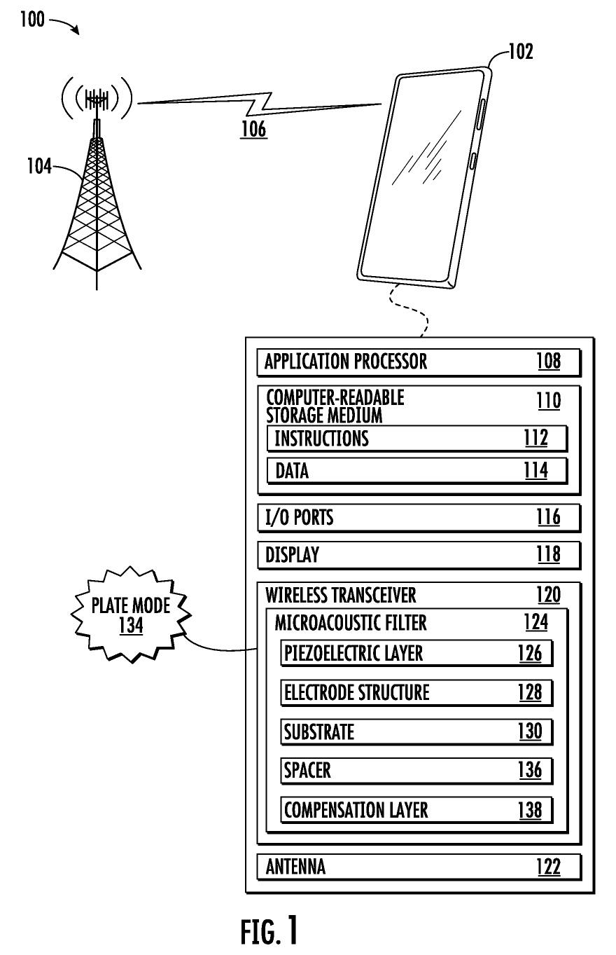

FIG. 1 illustrates an example environment 100 for operating a microacoustic filter with bilateral TCF compensation layers on the piezoelectric layer. In the environment 100, a computing device 102 communicates with a base station 104 through a wireless communication link 106 (wireless link 106). In this example, the computing device 102 is depicted as a smartphone. However, the computing device 102 can be implemented as any suitable computing or electronic device, such as a modem, a cellular base station, a broadband router, an access point, a cellular phone, a gaming device, a navigation device, a media device, a laptop computer, a desktop computer, a tablet computer, a wearable computer, a server, a network-attached storage (NAS) device, a smart appliance or other internet of things (IoT) device, a medical device, a vehicle-based communication system, a radar, a radio apparatus, and so forth. Use of a microacoustic filter is not limited to wireless communication as a microacoustic filter can be applied in any technological field where such filtering is useful.

The base station 104 communicates with the computing device 102 via the wireless link 106, which can be implemented as any suitable type of wireless link. Although depicted as a tower of a cellular network, the base station 104 can represent or be implemented as another device, such as a satellite, a server device, a terrestrial television broadcast tower, an access point, a peer-to-peer device, a mesh network node, and so forth. Therefore, the computing device 102 may communicate with the base station 104 or another device via a wireless connection.

The wireless link 106 can include a downlink of data or control information communicated from the base station 104 to the computing device 102, an uplink of other data or control information communicated from the computing device 102 to the base station 104, or both a downlink and an uplink. The wireless link 106 can be implemented using any suitable communication protocol or standard, such as 2nd-generation (2G), 3rd-generation (3G), 4th-generation (4G), 5th-generation (5G), or 6^{th}-generation (6G) cellular; IEEE 802.11 (e.g., Wi-Fi^{®}); IEEE 802.15 (e.g., Bluetooth^{®}); IEEE 802.16 (e.g., WiMAX^{®}); and so forth. In some implementations, the wireless link 106 may wirelessly provide power and the base station 104 or the computing device 102 may comprise a power source.

As shown, the computing device 102 includes an application processor 108 and a computer-readable storage medium 110 (CRM 110). The application processor 108 can include any type of processor, such as a multi-core processor, that executes processor-executable code stored by the CRM 110. The CRM 110 can include any suitable type of data storage media, such as volatile memory (e.g., random access memory (RAM)), non-volatile memory (e.g., Flash memory), optical media, magnetic media (e.g., disk), and so forth. In the context of this disclosure, the CRM 110 is implemented to store instructions 112, data 114, and other information of the computing device 102 and thus does not include transitory propagating signals or carrier waves.

The computing device 102 can also include input/output ports 116 (I/O ports 116) and a display 118. The I/O ports 116 enable data exchanges or interaction with other devices, networks, or users. The I/O ports 116 can include serial ports (e.g., universal serial bus (USB) ports), parallel ports, audio ports, infrared (IR) ports, user interface ports such as a touchscreen, and so forth. The display 118 presents graphics of the computing device 102, such as a user interface associated with an operating system, program, or application. Alternatively or additionally, the display 118 can be implemented as a display port or virtual interface, through which graphical content of the computing device 102 is presented.

A wireless transceiver 120 of the computing device 102 provides connectivity to respective networks and other electronic devices connected therewith. The wireless transceiver 120 can facilitate communication over any suitable type of wireless network, such as a wireless local area network (WLAN), peer-to-peer (P2P) network, mesh network, cellular network, ultra-wideband (UWB) network, wireless wide-area-network (WWAN), and/or wireless personal-area-network (WPAN). In the context of the example environment 100, the wireless transceiver 120 enables the computing device 102 to communicate with the base station 104 and networks connected therewith. However, the wireless transceiver 120 can also enable the computing device 102 to communicate “directly” with other devices or networks.

The wireless transceiver 120 includes circuitry and logic for transmitting and receiving communication signals via an antenna 122. Components of the wireless transceiver 120 can include amplifiers, switches, mixers, analog-to-digital converters, filters, and so forth for conditioning the communication signals (e.g., for generating or processing signals). The wireless transceiver 120 can also include logic to perform in-phase/quadrature (I/Q) operations, such as synthesis, encoding, modulation, decoding, demodulation, and so forth. In some cases, components of the wireless transceiver 120 are implemented as separate transmitter and receiver entities. Additionally or alternatively, the wireless transceiver 120 can be realized using multiple or different sections to implement respective transmitting and receiving operations (e.g., separate transmit and receive chains). In general, the wireless transceiver 120 processes data and/or signals associated with communicating data of the computing device 102 over the antenna 122.

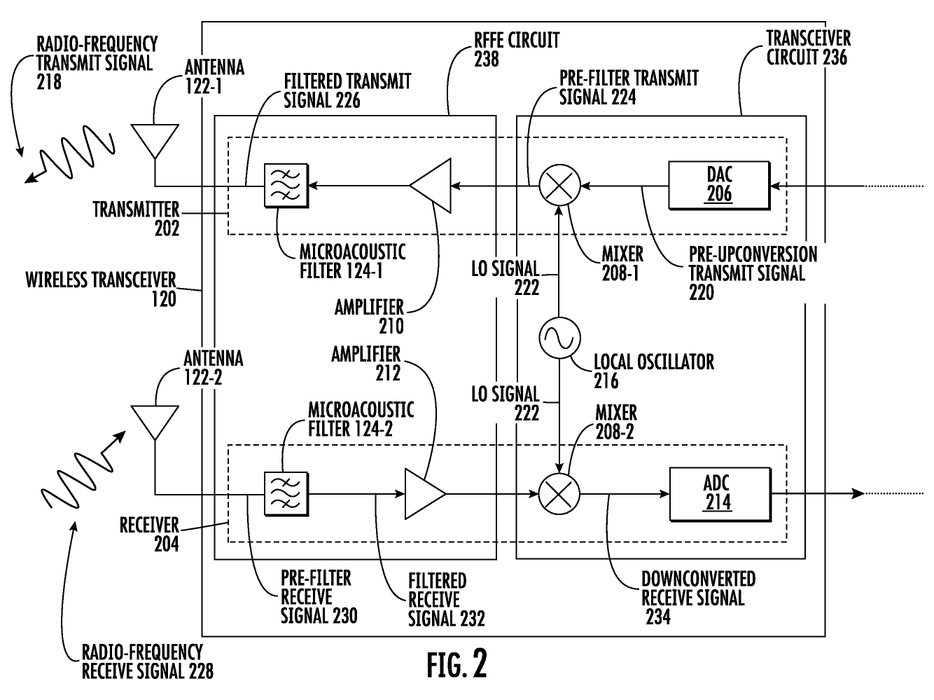

In the example shown in FIG. 1, the wireless transceiver 120 includes at least one microacoustic filter 124 (e.g., an acoustic filter, a plate-mode acoustic-wave filter, or a membrane-type filter). In some implementations, the wireless transceiver 120 includes multiple microacoustic filters 124, which can be formed from microacoustic resonators arranged in series, in parallel, in a ladder structure, in a lattice structure, or some combination thereof. The microacoustic filter 124 includes at least one piezoelectric layer 126, at least one electrode structure 128, and a substrate 130. It is possible to implement the substrate 130 as a single layer or as a substrate stack, as further described with respect to FIG. 2.

Although the microacoustic filter 124 can be any type of microacoustic filter, the techniques for implementing bilateral TCF compensation layers 138 on a piezoelectric layer 126 in which the electrode structure 128 laterally excites the piezoelectric layer 126 for a plate mode 134 can be particularly advantageous for reducing TCF while maintaining sufficient electromechanical coupling. The plate mode 134 can be a first order antisymmetric Lamb mode (e.g., an A1 mode). Other order modes are also possible. The plate mode 134 can be referred to as a laterally-excited plate mode, as further explained below.

The piezoelectric layer 126 has a crystalline structure operative to laterally excite the plate mode 134. The laterally-excited plate mode 134 forms an acoustic wave that causes different portions (e.g., an upper portion and a lower portion) of the piezoelectric layer 126 to move in opposite directions along a horizontal dimension. In other words, the laterally-excited plate mode 134 causes displacement and elongation to occur along the horizontal dimension while propagation of the wavefronts occurs along a vertical dimension of the piezoelectric layer 126. The wavefronts are vertically reflected at the free surface of the piezoelectric layer 126. The plate mode 134 is a quasi-stationary mode with approximately a zero group velocity in the lateral direction in the case of large pitches significantly exceeding a thickness of the piezoelectric layer 126.

The electrode structure 128 is positioned between the piezoelectric layer 126 and the substrate 130 and may be separated from the piezoelectric layer 126 by a compensation layer 138 but still able to induce an electric field in the piezoelectric layer 126. In some examples, the electrode structure 128 may be decoupled from the piezoelectric layer 126. In such examples, the microacoustic filter 124 may include at least one spacer layer 136, which suspends the piezoelectric layer 126 “above” or apart from the electrode structure 128. As such, the electrode structure 128 is, at least locally, physically separated from the piezoelectric layer 126 and may include a cavity (or gap) between the electrode structure 128 and the piezoelectric layer 126. In this regard, a TCF compensation layer 138 may be disposed between the electrode structure 128 and the piezoelectric layer 126.

With these improvements, the microacoustic filter 124 can be designed to support frequency ranges above 2 GHz, including frequencies between approximately 2 and 20 GHz. For example, the microacoustic filter 124 can be designed to have a resonance frequency between approximately 4 and 18 GHz, between approximately 7.5 and 17 GHz, or equal to approximately 4, 5, 6, 10, 13, 15, 17, or 20 GHz. In general, the term “approximately” can mean that any of the frequencies can be within ± 10% of a specified value or less (e.g., within ± 5%, ± 3%, or ± 2% of a specified value). The microacoustic filter 124 is further described with respect to Figure 2.

FIG. 2 illustrates an example wireless transceiver 120. In the depicted configuration, the wireless transceiver 120 includes a transmitter 202 and a receiver 204, which are respectively coupled to a first antenna 122-1 and a second antenna 122-2. In other implementations, the transmitter 202 and the receiver 204 can be connected to a same antenna through a duplexer (not shown). The transmitter 202 is shown to include at least one digital-to-analog converter 206 (DAC 206), at least one first mixer 208-1, at least one amplifier 210 (e.g., a power amplifier), and at least one first microacoustic filter 124-1. The receiver 204 includes at least one second microacoustic filter 124-2, at least one amplifier 212 (e.g., a low-noise amplifier), at least one second mixer 208-2, and at least one analog-to-digital converter 214 (ADC 214). The first mixer 208-1 and the second mixer 208-2 are coupled to a local oscillator 216. Although not explicitly shown, the DAC 206 of the transmitter 202 and the ADC 214 of the receiver 204 can be coupled to the application processor 108 (of FIG. 1) or another processor associated with the wireless transceiver 120 (e.g., a modem).

In some implementations, the wireless transceiver 120 is implemented using multiple circuits (e.g., multiple integrated circuits), such as a transceiver circuit 236 and a radio-frequency front-end (RFFE) circuit 238. As such, the components that form the transmitter 202 and the receiver 204 are distributed across these circuits. As shown in FIG. 2, the transceiver circuit 236 includes the DAC 206 of the transmitter 202, the mixer 208-1 of the transmitter 202, the mixer 208-2 of the receiver 204, and the ADC 214 of the receiver 204. In other implementations, the DAC 206 and the ADC 214 can be implemented on another separate circuit that includes the application processor 108 or the modem. The RFFE circuit 238 includes the amplifier 210 of the transmitter 202, the microacoustic filter 124-1 of the transmitter 202, the microacoustic filter 124-2 of the receiver 204, and the amplifier 212 of the receiver 204.

During transmission, the transmitter 202 generates a radio-frequency transmit signal 218, which is transmitted using the antenna 122-1. To generate the radio-frequency transmit signal 218, the DAC 206 provides a pre-upconversion transmit signal 220 to the first mixer 208-1. The pre-upconversion transmit signal 220 can be a baseband signal or an intermediate-frequency signal. The first mixer 208-1 upconverts the pre-upconversion transmit signal 220 using a local oscillator (LO) signal 222 provided by the local oscillator 216. The first mixer 208-1 generates an upconverted signal, which is referred to as a pre-filter transmit signal 224. The pre-filter transmit signal 224 can be a radio-frequency signal and include some noise or unwanted frequencies, such as a harmonic frequency. The amplifier 210 amplifies the pre-filter transmit signal 224 and passes the amplified pre-filter transmit signal 224 to the first microacoustic filter 124-1.

The first microacoustic filter 124-1 filters the amplified pre-filter transmit signal 224 to generate a filtered transmit signal 226. As part of the filtering process, the first microacoustic filter 124-1 attenuates the noise or unwanted frequencies within the pre-filter transmit signal 224. The transmitter 202 provides the filtered transmit signal 226 to the antenna 122-1 for transmission. The transmitted filtered transmit signal 226 is represented by the radio-frequency transmit signal 218.

During reception, the antenna 122-2 receives a radio-frequency receive signal 228 and passes the radio-frequency receive signal 228 to the receiver 204. The second microacoustic filter 124-2 accepts the received radio-frequency receive signal 228, which is represented by a pre-filter receive signal 230. The second microacoustic filter 124-2 filters any noise or unwanted frequencies within the pre-filter receive signal 230 to generate a filtered receive signal 232.

The amplifier 212 of the receiver 204 amplifies the filtered receive signal 232 and passes the amplified filtered receive signal 232 to the second mixer 208-2. The second mixer 208-2 downconverts the amplified filtered receive signal 232 using the LO signal 222 to generate the downconverted receive signal 234. The ADC 214 converts the downconverted receive signal 234 into a digital signal, which can be processed by the application processor 108 or another processor associated with the wireless transceiver 120 (e.g., the modem).

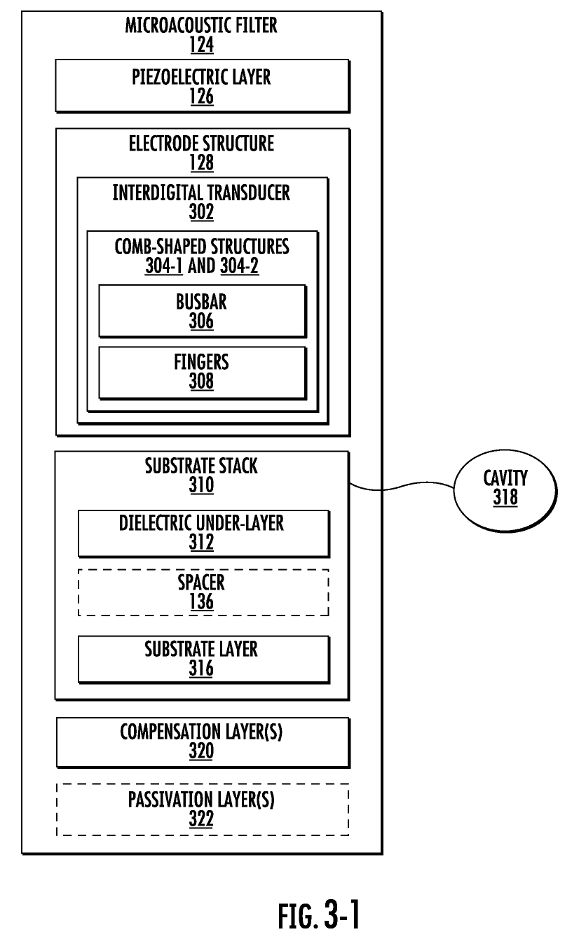

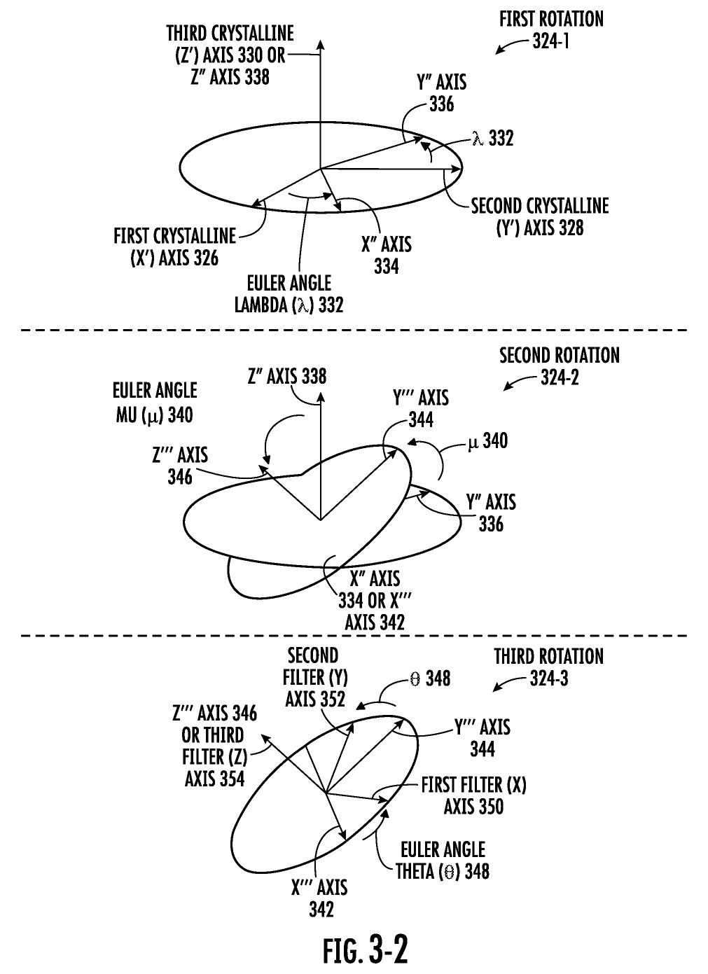

FIG. 2 illustrates one example configuration of the wireless transceiver 120. Other configurations of the wireless transceiver 120 can support multiple frequency bands and share an antenna 122 across multiple transceivers. One of ordinary skill in the art can appreciate the variety of other configurations for which microacoustic filters 124 may be included. For example, the microacoustic filters 124 can be integrated within duplexers or diplexers of the wireless transceiver 120. Example implementations of the microacoustic filter 124-1 or 124-2 are further described with respect to FIG. 3-1.

FIG. 3-1 illustrates example components of the microacoustic filter 124. In the depicted configuration, the microacoustic filter 124 includes the piezoelectric layer 126 and the electrode structure 128. In example implementations, the piezoelectric layer 126 can be implemented using a variety of different materials that exhibit piezoelectric properties (e.g., can transfer mechanical energy into electrical energy or electrical energy into mechanical energy). Example types of material include lithium niobate (LiNbO₃), lithium tantalate (LiTaO₃), or some combination thereof. In general, the material that forms the piezoelectric layer 126 may have a crystalline structure. This crystalline structure is defined by an ordered arrangement of particles (e.g., atoms, ions, or molecules). The orientation of the crystalline structure of the piezoelectric layer 126 can be defined by Euler angles lambda (λ), mu (µ), and theta (θ).

In some aspects, the material and crystalline structure of the piezoelectric layer 126 is selected such that the plate mode 134 can be laterally excited within the piezoelectric layer 126. Consider two examples in which the piezoelectric layer 126 is formed using lithium niobate. In a first example implementation, the lithium niobate material is cut such that a value of the Euler angle mu (µ) is approximately 32.5° and values of the Euler angles lambda (λ) and theta (θ) are approximately 0° (or at least one symmetrical equivalent thereof). In a second example implementation, the lithium niobate material is cut such that a value of the Euler angle theta (θ) is approximately 90° and values of the Euler angles lambda (λ) and mu (µ) are approximately 0° (or at least one symmetrical equivalent thereof). In general, the term “approximately” can mean that any of the angles can be within ± 10% of a specified value or less (e.g., within ± 5%, ± 3%, or ± 2% of a specified value).

In another example, the piezoelectric layer 126 is formed using lithium tantalate. In this case, the lithium tantalate material is cut such that a value of the Euler angle mu (µ) is approximately 36° and values of the Euler angles lambda (λ) and theta (θ) are approximately 0° (or at least one symmetrical equivalent thereof). In general, the term “approximately” can mean that any of the angles can be within ± 10% of a specified value or less (e.g., within ± 5%, ± 3%, or ± 2% of a specified value). The Euler angles are further described with respect to FIG. 3-2.

For the plate mode 134, a resonance frequency of the microacoustic filter 124 is determined, at least in part, by a thickness of the piezoelectric layer 126. To realize a resonance frequency between 4 and 15 GHz, the thickness of the piezoelectric layer 126 can be between approximately 100 and 400 nanometers (nm), for instance. Generally speaking, the thickness of the piezoelectric layer 126 and the resonance frequency are inversely related. In other words, decreasing the thickness of the piezoelectric layer 126 increases the resonance frequency of the microacoustic filter 124, while increasing the thickness of the piezoelectric layer 126 decreases the resonance frequency of the microacoustic filter 124.

The electrode structure 128 comprises an electrically conductive material, such as metal, and can include one or more layers. The one or more layers can include one or more electrically conductive layers and can optionally include one or more adhesion layers. As an example, the electrically conductive layers can be composed of aluminum (Al), copper (Cu), silver (Ag), gold (Au), tungsten (W), silicon (Si), or some combination or doped version thereof. The adhesion layers can be composed of chromium (Cr), titanium (Ti), molybdenum (Mo), or some combination thereof.

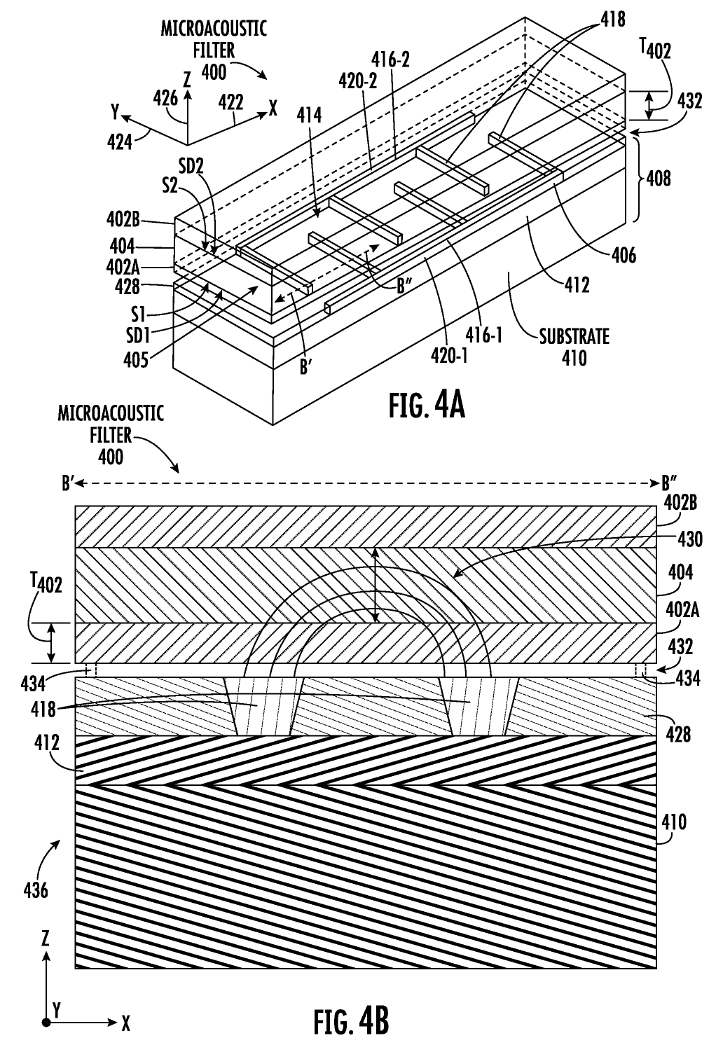

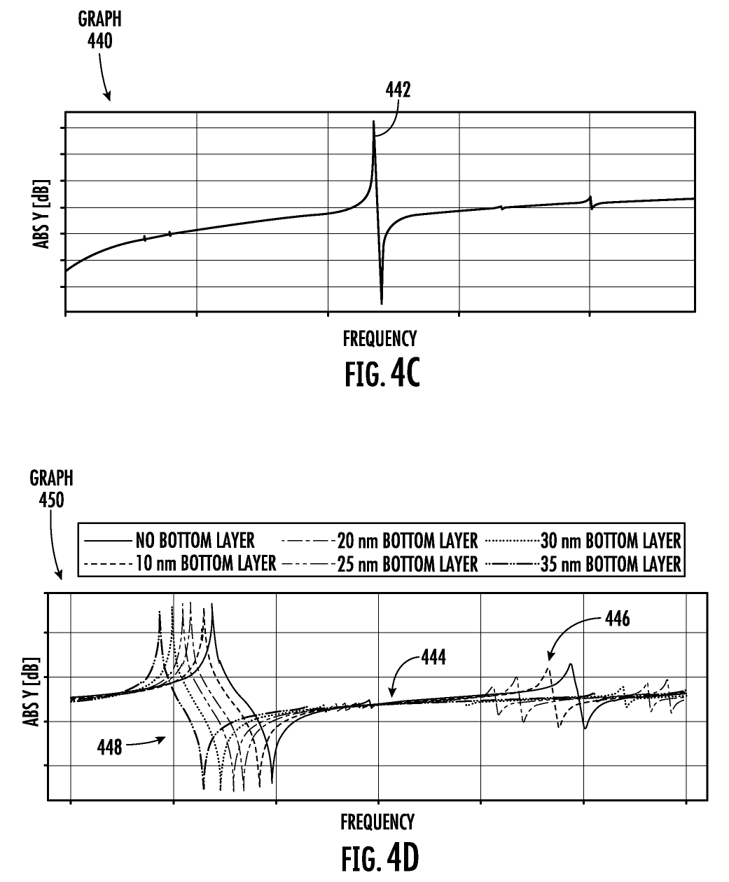

The electrode structure 128 can include one or more interdigital transducers 302. The interdigital transducer 302 converts an electrical signal into an acoustic wave and converts the acoustic wave into a filtered electrical signal. The interdigital transducer 302 includes at least two comb-shaped structures 304-1 and 304-2. Each comb-shaped structure 304-1 and 304-2 includes a busbar 306 (e.g., a conductive segment or rail) and multiple fingers 308 (e.g., electrode fingers). An example interdigital transducer 302 is further described with respect to FIG. 4. Although not explicitly shown, the electrode structure 128 can also include two or more reflectors. In an example implementation, the interdigital transducer 302 is arranged between two reflectors.

The microacoustic filter 124 also includes a substrate stack 310, which represents an example implementation of the substrate 130 of FIG. 1. The substrate stack 310 includes a dielectric under-layer (DUL) 312 and a substrate layer 316. The substrate stack 310 may include an optional spacer layer 136. The DUL 312 bonds the electrode structure 128 to the substrate layer 316 and may function as a foundation or base for the optional spacer layer 136. However, in another example, the spacer layer 136 may be part of the substrate 130. In some examples, the substrate stack 310 defines a cavity 318 (or gap) between the piezoelectric layer 126 and the electrode structure 128. The cavity 318 can include a gas, such as air.

The substrate layer 316 is composed of material that is non-conducting and provides isolation. Example materials include silicon (Si), silicon dioxide (SiO₂), silicon carbide (SiC), sapphire, glass, or some combination or doped version thereof. In some implementations, the substrate layer 316 is composed of multiple layers. The multiple layers can be formed using the same material or different materials.

The microacoustic filter 124 can include TCF compensation layer(s) (“compensation layers”) 320 disposed bilaterally on the piezoelectric layer 126 to provide increased, balanced temperature compensation to enable the microacoustic filter 124 to achieve a target temperature coefficient of frequency based on the thickness of the piezoelectric layer 126. The compensation layers 320 may be the compensation layers 138 in FIG. 1. The compensation layers 320 can be formed on both surfaces of the piezoelectric layer 126 using silicon dioxide (SiO₂), fluorine-doped silicon dioxide (SiOₓF_{y}) or carbon-doped silicon dioxide (e.g., SiOₓC_{y}), for example.

The microacoustic filter 124 can include passivation layer(s) 322 disposed on the compensation layer 320. In such example implementation, the passivation layer 322 may be formed using silicon nitride (Si₃N₄). The passivation layer 322 can protect the underlying TCF compensation layer(s) from an external environment. In some examples, the thickness of the passivation layer 322 can further be used to adjust the frequency of the microacoustic filter 124.

In some aspects, the microacoustic filter 124 can be considered a resonator. Sometimes the microacoustic filter 124 can be connected to other resonators associated with different layer stacks from the microacoustic filter 124. In other aspects, the microacoustic filter 124 can be implemented as multiple interconnected resonators, which use the same layers (e.g., the piezoelectric layer 126, the TCF compensation layers 320, the electrode structure 128, and/or the substrate stack 310). Aspects of the piezoelectric layer 126 are further described with respect to FIG. 3-2.

FIG. 3-2 illustrates example Euler angles that define an orientation of the piezoelectric layer 126 relative to a crystalline structure of the material that forms the piezoelectric layer 126. In this example, the material that forms the piezoelectric layer 126 includes lithium niobate and/or lithium tantalate. A first crystalline (X’) axis 326, a second crystalline (Y’) axis 328, and a third crystalline (Z’) axis 330 are fixed along crystallographic axes of a lithium niobate crystal. A first rotation 324-1 is applied to rotate the first crystalline X’ axis 326 and the second crystalline Y’ axis 328 about the third crystalline Z’ axis 330. In particular, the first rotation 324-1 rotates the first crystalline X’ axis 326 in a direction of the second crystalline Y’ axis 328. The angle associated with the first rotation 324-1 characterizes one of the Euler angles, which is represented by Euler angle lambda (λ) 332. The resulting rotated axes are represented by a new set of axes: an X’’ axis 334, a Y’’ axis 336, and a Z’’ axis 338. As shown in Figure 3-2, the third crystalline Z’ axis 330 remains unchanged by the first rotation 324-1 such that the third crystalline Z’ axis 330 is equal to the Z’’ axis 338.

In a second rotation 324-2, the Y’’ axis 336 and the Z’’ axis 338 are rotated about the X’’ axis 334 by another Euler angle, which is represented by Euler angle mu (µ) 340. In this case, the Y’’ axis 336 is rotated in the direction of the Z’’ axis 338. The resulting rotated axes are represented by a new set of axes: an X’’’ axis 342, a Y’’’ axis 344, and a Z’’’ axis 346. As shown in FIG. 3-2, the X’’ axis 334 remains unchanged by the second rotation 324-2 such that the X’’ axis 334 is equal to the X’’’ axis 342.

In a third rotation 324-3, the X’’’ axis 342 and the Y’’’ 344 axis are rotated about the Z’’’ axis 346 by an additional Euler angle, which is represented by Euler angle theta (θ) 348. In this case, the X’’’ axis 342 is rotated in the direction of the Y’’’ axis 344. The resulting rotated axes are represented by a first filter (X) axis 350, a second filter (Y) axis 352, and a third filter (Z) axis 354, which respectively correspond to the X-axis, the Y-axis, and the Z-axis of FIG. 4A. As shown in FIGS. 3-2, the Z’’’ axis 346 remains unchanged by the third rotation 324-3 such that the Z’’’ axis 346 is equal to the third filter Z axis 354. The microacoustic filter 124 is further described with respect to FIG. 4A.

FIG. 4A illustrates a three-dimensional perspective view of a first example of the microacoustic filter 400 with the TCF compensation layers 402A, 402B disposed bilaterally on the piezoelectric layer 404. The TCF compensation layers 402A, 402B may comprise silicon dioxide (SiO₂), fluorine-doped silicon dioxide (SiOₓF_{y}) or carbon-doped silicon dioxide (e.g., SiOₓC_{y}), for example. The microacoustic filter 400 may be the microacoustic filter 124 in FIGS. 1 and 3-1. A two-dimensional cross-section view of the microacoustic filter 400 at cross-section B’-B’’ in FIG. 4A is shown in FIG. 4B. The microacoustic filter 400 includes the piezoelectric layer 404, the TCF compensation layers 402A, 402B, and an electrode structure 406. The TCF compensation layers 402A, 402B reduce the changes in frequency response of the microacoustic filter 400 in response to increases in temperature, which occur during normal operation. Having the TCF compensation layers 402A, 402B disposed bilaterally (i.e., on opposite surfaces) on the piezoelectric layer 404 also significantly reduces spurious modes in the frequency response compared to that of microacoustic filters including a TCF compensation layer on only one surface of the piezoelectric layer.

The piezoelectric layer 404 has a crystalline structure 405 operative to laterally excite a plate mode as discussed above with reference to FIG. 1. The electrode structure 406 is disposed on a first surface S1 of the piezoelectric layer 404. The first TCF compensation layer 402A is disposed on the first surface S1 of the piezoelectric layer 404 between the electrode structure 406 and the piezoelectric layer 404. The second TCF compensation layer 402B is disposed on a second surface S2 of the piezoelectric layer 404 opposite to the first surface S1. In this regard, the piezoelectric layer 404 is sandwiched between the first TCF compensation layer 402A and the second TCF compensation layer 402B. With the TCF compensation layers 402A, 402B disposed bilaterally (on the first surface S1 and the second surface S2) on the piezoelectric layer 404, the TCF of the piezoelectric layer 404 is significantly reduced, which in turn suppresses spurious modes in the microacoustic filter 400. The first surface S1 is on a first side SD1 of the piezoelectric layer 404 and the second surface S2 is on a second side SD2 of the piezoelectric layer 404.

The microacoustic filter 400 may be disposed on the substrate stack 408, which includes a substrate 410 and a dielectric under-layer (DUL) 412. Thus, the electrode structure 406 is disposed between the substrate 410 and the first TCF compensation layer 402A. The dielectric under-layer 412 is disposed between the electrode structure 406 and the substrate 410.

The electrode structure 406 can include one or more interdigital transducers (IDTs) 414. In FIG. 4A, the interdigital transducer 414 is shown to have two comb-shaped structures 416-1 and 416-2 with fingers 418 extending from two busbars 420-1, 420-2 towards each other. The fingers 418 are arranged in an interlocking manner in between the two busbars 420-1, 420-2 of the interdigital transducer 414 (e.g., arranged in an interdigitated manner). In other words, the fingers 418 connected to the first busbar 420-1 extend towards the second busbar 420-2 but do not connect to the second busbar 420-2. Likewise, the fingers 418 connected to the second busbar 420-2 extend towards the first busbar 420-1 but do not connect to the first busbar 420-1.

In the X-axis direction along the busbars 420-1, 420-2, a portion of one finger 308 overlaps with a portion of an adjacent finger 418 in a central region, which may be referred to as the aperture, track, or active region where electric fields are produced between fingers 418 to cause an acoustic wave to form at least in this region of the piezoelectric layer 404.

A periodicity of the fingers 418 in the X-axis direction is referred to as a pitch P₄₁₈ of the interdigital transducer 414. The pitch P₄₁₈ may be indicated in various ways. For example, in certain aspects, the pitch P₄₁₈ may correspond to a magnitude of a distance between adjacent fingers 418 of the interdigital transducer 414 in the central region. This distance may be defined, for example, as the distance between center points of each of the fingers 418. The distance may be generally measured between a right (or left) edge of one finger 418 and the right (or left) edge of an adjacent finger 418 when the fingers 418 have uniform widths. In certain aspects, an average of distances between adjacent fingers 418 of the interdigital transducer 414 may be used for the pitch P₄₁₈. The pitch P₄₁₈ can be determined to adjust the static capacitance and/or suppress spurious modes. The pitch P₄₁₈ may also be determined to adjust the resonance frequency.

In FIG. 4A, the microacoustic filter 400 is described with reference to a first axis (X-axis) 422, a second axis (Y-axis) 424, and a third axis (Z-axis) 426. The first axis 422 and the second axis 424 are parallel to a planar surface of the piezoelectric layer 404, and the second axis 424 is orthogonal to the first axis 422. The third (Z-) axis 426 is normal (e.g., orthogonal) to a (e.g., planar) surface S1 of the piezoelectric layer 404. The busbars 420-1, 420-2 of the interdigital transducer 414 are oriented to be parallel to the first axis 422. The fingers 418 of the interdigital transducer 414 are oriented to extend parallel to the second axis 424. The fingers 418 generate an electric field in a direction that is substantially parallel to the first axis 422. This electric field can excite a quasi-stationary acoustic wave within the piezoelectric layer 404 between adjacent fingers 418 of the electrode structure 406. Due to the crystalline structure 405 of the piezoelectric layer 404 and the selected crystal cut, the lateral components of the electric field excite the plate mode within the piezoelectric layer 404. Hence, the microacoustic filter 400 can be considered to operate with a laterally-excited plate mode.

The microacoustic filter 400 may include an interstitial dielectric material 428 disposed between the first TCF compensation layer 402A and the dielectric under-layer 412 in the Z-axis direction and also disposed between the fingers 418 in a direction orthogonal to the Z-axis direction (e.g., in a plane defined by the X-axis direction and the Y-axis direction) in FIG. 4A. The interstitial dielectric material 428 may comprise silicon dioxide (SiO₂). In some examples, the interstitial dielectric material 428 may be formed as a uniform layer that is subsequently patterned and/or etched to form channels in which the fingers 418 and the busbars 420-1, 420-2 are formed. Thus, each of the interstitial dielectric material 428 and the electrode fingers 418 have a first thickness T₄₁₈ orthogonal to the first surface S1 of the piezoelectric layer 404.

During operation, the microacoustic filter 400 receives a radio-frequency signal, such as the pre-filter transmit signal 224 or the pre-filter receive signal 230 shown in FIG. 2. The electrode structure 406 excites the acoustic wave within the piezoelectric layer 404 using the inverse piezoelectric effect. For example, the interdigital transducer 414 in the electrode structure 406 generates an alternating electric field based on the received radio-frequency signal. The piezoelectric layer 404 enables the acoustic wave to be formed in response to the alternating electric field generated by the interdigital transducer 414. In other words, the piezoelectric layer 404 causes, at least partially, an acoustic wave to form responsive to electrical stimulation by one or more interdigital transducers 414.

The acoustic wave forms within the piezoelectric layer 404 and interacts with the interdigital transducer 414 or another interdigital transducer within the electrode structure 406 (not shown in FIG. 4A). Using the piezoelectric effect, the electrode structure 406 generates a filtered radio-frequency signal based on the formed acoustic wave. In particular, the piezoelectric layer 404 generates an alternating electric field due to the mechanical stress generated by the acoustic wave. The alternating electric field induces a time-varying voltage in the interdigital transducer 414. This oscillating voltage forms the filtered radio-frequency signal, which is provided at an output of the microacoustic filter 124. The filtered radio-frequency signal can include the filtered transmit signal 226, or the filtered receive signal 232 of FIG. 2.

It should be appreciated that while a certain number of fingers 418 are illustrated in FIG. 4A, the number of actual fingers and lengths and widths of the fingers and busbars may be different in an actual implementation. Such parameters depend on the particular application and desired filter characteristics. In addition, the microacoustic filter 400 can include multiple interconnected electrode structures 406, each including multiple interdigital transducers 414 to achieve a desired passband (e.g., multiple interconnected resonators or interdigital transducers 414 in series or parallel connections to form a desired filter transfer function).

It also should be noted that the fingers 418 are separated from the first TCF compensation layer 402A by a cavity or gap 432, which may be an air gap, to effectively isolate the piezoelectric layer 404 from the substrate 410 to reduce losses.

FIG. 4B is a view of a cross-section B’-B” of the microacoustic filter 400 in FIG. 4A illustrating an example of electric field 430 that may be induced in the piezoelectric layer 404 in response to a signal received in the fingers 418 of the electrode structure 406 in FIG. 4A, despite the presence of the cavity 432, and a direction of movement in the piezoelectric layer 404 in response to the electric field 430. The TCF compensation layers 402A, 402B formed on opposite surfaces of the piezoelectric layer 404 each have a thickness T₄₀₂. FIG. 4B also shows the dielectric under-layer 412 disposed on the substrate 410 and the fingers 418 of the electrode structure 406 disposed on the dielectric under-layer 412. The interstitial dielectric material 428 is disposed between the TCF compensation layer 402A and the dielectric under-layer 412 in the Z-axis direction and between the respective fingers 418 in the X-axis direction. FIG. 4B shows a cavity 432 in the microacoustic filter 400 corresponding to the cavity 318 in FIG. 3-1, which is provided to acoustically decouple the piezoelectric layer 404 from the electrode structure 406. However, the fingers 418 still generate the electric field 430 extending across the cavity 432 and the TCF compensation layer 402A and into the piezoelectric layer 404. As indicated in FIG. 4B, the electric field induced in the piezoelectric layer 404 causes acoustic waves to propagate in the Z-axis direction. In some examples, the cavity 432 may be maintained between the first TCF compensation layer 402A and the interstitial dielectric material 428 by walls or pillars 434, which allow minimal acoustic losses to the substrate 410. Alternatively, an external frame structure (not shown) may be provided to maintain the cavity 432.

In some examples, the cavity 432 may be omitted from a microacoustic filter, in which case the piezoelectric layer would not be acoustically decoupled from the substrate stack 408. In the absence of the cavity 432, the substrate stack 408 may further include layers (not shown) to provide acoustic reflection, such as a Bragg mirror.

As noted above, the first TCF compensation layer 402A and the second TCF compensation layer 402B may be formed of silicon dioxide (SiO₂). In this regard, in some examples, the first TCF compensation layer 402A and the second TCF compensation layer 402B may also be referred to herein as a first dielectric layer 402A and a second dielectric layer 402B, respectively. In addition, in some examples, the interstitial dielectric layer 428, the dielectric under-layer 412, and the substrate 410 may be referred to as a “carrier stack” 436.

FIG. 4C is a graph 440 of frequency response 442 of the microacoustic filter 400 in FIGS. 4A and 4B. The frequency response 442 shows resonance at a desired frequency with reduced spurious modes as a result of the bilateral TCF compensation layers 402A, 402B disposed on the piezoelectric layer 404 in FIGS. 4A and 4B.

FIG. 4D is a graph 450 of frequency responses 444 of examples of the microacoustic filter 400 in FIGS. 4A and 4B having the TCF compensation layers 402A, 402B in a range of thicknesses T₄₀₂ from zero (0) nanometers (nm) to thirty-five (35) nm. As shown, spurious modes 446 occurring in the frequency responses 444 may be significantly reduced by including bilateral TCF compensation layers 402A, 402B of appropriate thicknesses T_{402,} and the resonant frequencies 448 of the microacoustic filter 400 may be shifted as needed by adjusting the thickness T₄₀₂.

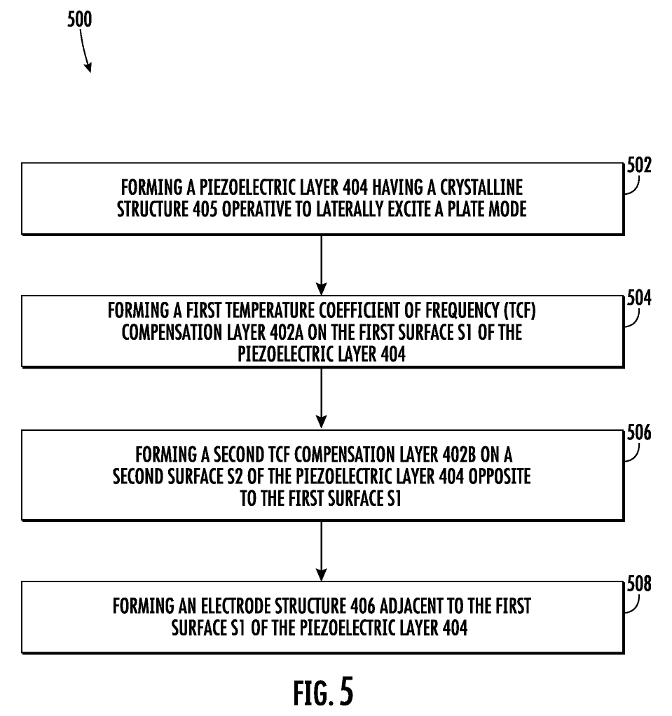

FIG. 5 is a flow chart of a method 500 of making the microacoustic filter 400 in FIGS. 4A and 4B. The method 500 includes forming a piezoelectric layer 404 having a crystalline structure 405 operative to laterally excite a plate mode (block 502) and forming a first temperature coefficient of frequency (TCF) compensation layer 402A on the first surface S1 of the piezoelectric layer 404 (block 504). The method 500 includes forming a second TCF compensation layer 402B on a second surface S2 of the piezoelectric layer 404 adjacent to the first surface S1 (block 506) and forming an electrode structure 406 opposite to the first surface S1 of the piezoelectric layer 404 (block 508).

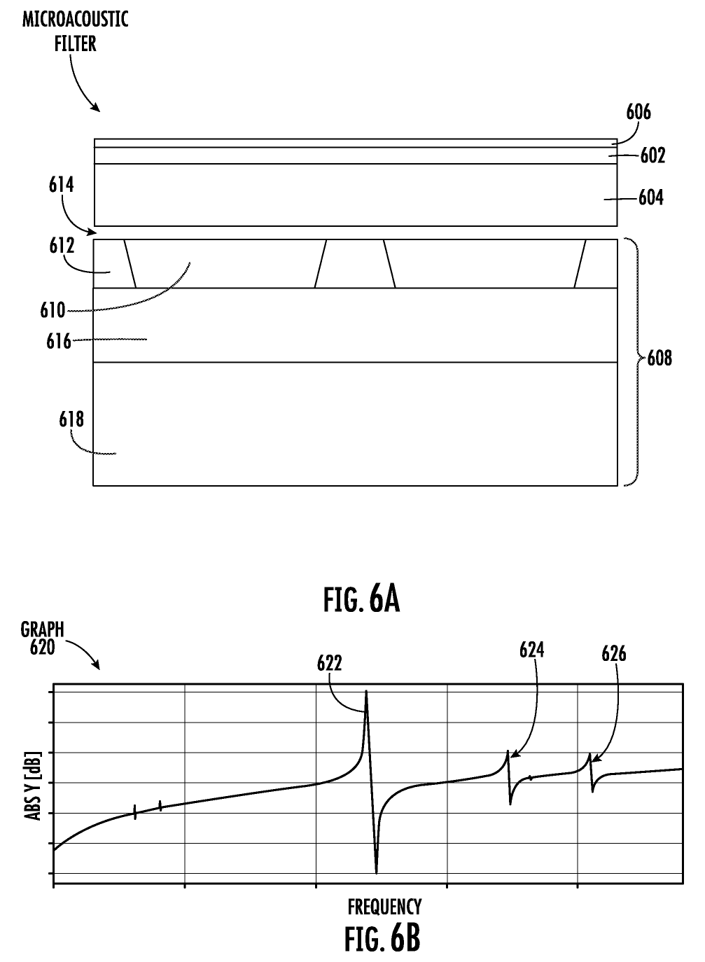

FIG. 6A is a cross-sectional side view of a microacoustic filter 600 configured to operate in a plate mode and employing a TCF compensation layer 602 on only an upper surface SU₆₀₄ of a piezoelectric layer 604. The microacoustic filter 600 includes a passivation layer 606 disposed on the TCF compensation layer 602 for protection against environmental factors. The microacoustic filter 600 includes a substrate stack 608, which may be the substrate stack 408 in FIGS. 4A and 4B, including an electrode structure 610 and an interstitial dielectric material 612 separated from the piezoelectric layer 604 by a cavity 614, which provides acoustic decoupling of the piezoelectric layer 604 and the substrate stack 608. The substrate stack 608 further includes a dielectric under-layer 616 disposed between the electrode structure 610 and a substrate 618. The microacoustic filter 600 corresponds in most aspects to the microacoustic filter 400 in FIGS. 4A and 4B, except with regard to the lack of a TCF compensation layer on a bottom surface SB₆₀₄ of the piezoelectric layer 604.

FIG. 6B is a graph 620 of frequency response 622 of the microacoustic filter 600 shown in FIG. 6A, which is provided for comparison to the graphs in FIGS. 4C and 4D. In this regard, the graph 620 shows that the microacoustic filter 600 suffers from strong spurious modes 624 and 626 at frequencies outside the desired resonant frequency range.

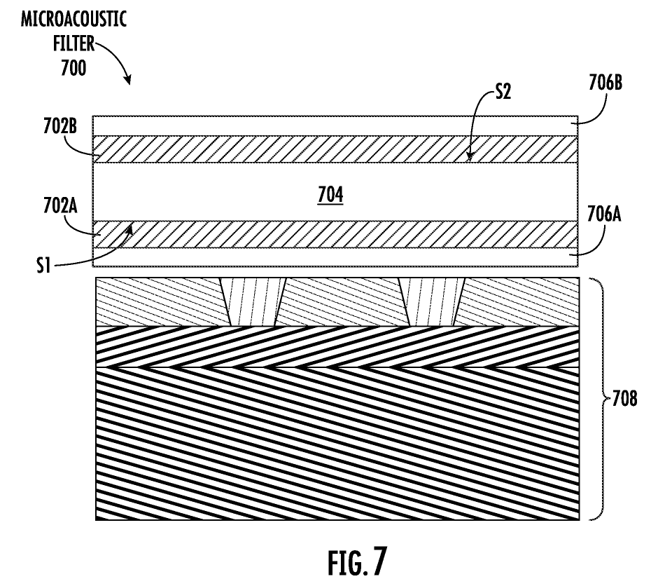

FIG. 7 is a cross-sectional side view of another example of a microacoustic filter 700, which corresponds to the microacoustic filter 400 in FIGS. 4A and 4B, including a first TCF compensation layer 702A on a first side S1 of a piezoelectric layer 704 and a second TCF compensation layer 702B on a second side S2 of the piezoelectric layer 704 opposite to the first side S1. However, the microacoustic filter 700 additionally includes passivation layers 706A, 706B formed on the respective TCF compensation layers 702A, 702B. A substrate stack 708 corresponds to the substrate stack 408 in FIG. 4A. The microacoustic filter 700 may achieve a frequency response similar to those shown in FIGS. 4C and 4D, having reduced spurious modes compared to the microacoustic filter 600 in FIG. 6A. The passivation layers 706A, 706B provide protection of the microacoustic filter 700 from environmental factors. In particular, the TCF compensation layers 702A, 702B are protected by the passivation layers 706A, 706B without significantly affecting operation of the microacoustic filter 700.

Microacoustic filters 400 and 700, having TCF compensation layers bilaterally disposed on the piezoelectric layer to reduce spurious modes, may be integrated into any processor-based device. Examples of such processor-based devices, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

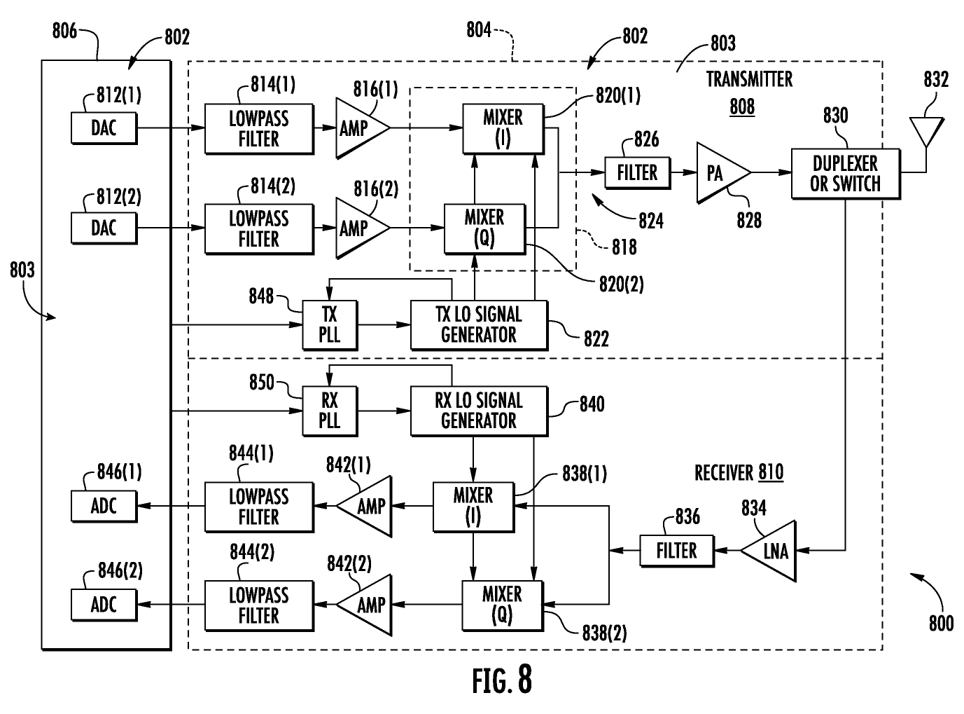

FIG. 8 illustrates an exemplary wireless communications device 800 that includes radio-frequency (RF) components formed from one or more ICs 802, wherein any of the ICs 802 may include microacoustic filters 400 and 700 having TCF compensation layers bilaterally disposed on their piezoelectric layers 404 and 704 to reduce spurious modes, as shown in FIGS. 4A, 4B, and 7. The wireless communications device 800 may include or be provided in any of the above-referenced devices, as examples. As shown in FIG. 8, the wireless communications device 800 includes a transceiver 804 and a data processor 806. The data processor 806 may include a memory to store data and program codes. The transceiver 804 includes a transmitter 808 and a receiver 810 that support bi-directional communications. In general, the wireless communications device 800 may include any number of transmitters 808 and/or receivers 810 for any number of communication systems and frequency bands. All or a portion of the transceiver 804 may be implemented on one or more analog ICs, RF ICs (RFICs), mixed-signal ICs, etc.

The transmitter 808 or the receiver 810 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage and then from IF to baseband in another stage for the receiver 810. In the direct-conversion architecture, a signal is frequency-converted between RF and baseband in one stage. The super-heterodyne and direct-conversion architectures may use different circuit blocks and/or have different requirements. In the wireless communications device 800 in FIG. 8, the transmitter 808 and the receiver 810 are implemented with the direct-conversion architecture.

In the transmit path, the data processor 806 processes data to be transmitted and provides I and Q analog output signals to the transmitter 808. In the exemplary wireless communications device 800, the data processor 806 includes digital-to-analog converters (DACs) 812(1), 812(2) for converting digital signals generated by the data processor 806 into the I and Q analog output signals (e.g., I and Q output currents) for further processing.

Within the transmitter 808, lowpass filters 814(1), 814(2) filter the I and Q analog output signals, respectively, to remove undesired signals caused by the prior digital-to-analog conversion. Amplifiers (AMPs) 816(1), 816(2) amplify the signals from the lowpass filters 814(1), 814(2), respectively, and provide I and Q baseband signals. An upconverter 818 upconverts the I and Q baseband signals with I and Q transmit (TX) local oscillator (LO) signals through mixers 820(1), 820(2) from a TX LO signal generator 822 to provide an upconverted signal 824. A filter 826 filters the upconverted signal 824 to remove undesired signals caused by the frequency up-conversion as well as noise in a receive frequency band. A power amplifier (PA) 828 amplifies the upconverted signal 824 from the filter 826 to obtain the desired output power level and provides a transmit RF signal. The transmit RF signal is routed through a duplexer or switch 830 and transmitted via an antenna 832.

In the receive path, the antenna 832 receives signals transmitted by base stations and provides a received RF signal, which is routed through the duplexer or switch 830 and provided to a low noise amplifier (LNA) 834. The duplexer or switch 830 is designed to operate with a specific receive (RX)-to-TX duplexer frequency separation, such that RX signals are isolated from TX signals. The received RF signal is amplified by the LNA 834 and filtered by a filter 836 to obtain a desired RF input signal. Down-conversion mixers 838(1), 838(2) mix the output of the filter 836 with I and Q RX LO signals (i.e., LO_I and LO_Q) from an RX LO signal generator 840 to generate I and Q baseband signals. The I and Q baseband signals are amplified by AMPs 842(1), 842(2) and further filtered by lowpass filters 844(1), 844(2) to obtain I and Q analog input signals, which are provided to the data processor 806. In this example, the data processor 806 includes analog-to-digital converters (ADCs) 846(1), 846(2) for converting the analog input signals into digital signals to be further processed by the data processor 806.

In the wireless communications device 800 of FIG. 8, the TX LO signal generator 822 generates the I and Q TX LO signals used for frequency up-conversion, while the RX LO signal generator 840 generates the I and Q RX LO signals used for frequency down-conversion. Each LO signal is a periodic signal with a particular fundamental frequency. A TX phase-locked loop (PLL) circuit 848 receives timing information from the data processor 806 and generates a control signal used to adjust the frequency and/or phase of the TX LO signals from the TX LO signal generator 822. Similarly, an RX PLL circuit 850 receives timing information from the data processor 806 and generates a control signal used to adjust the frequency and/or phase of the RX LO signals from the RX LO signal generator 840.

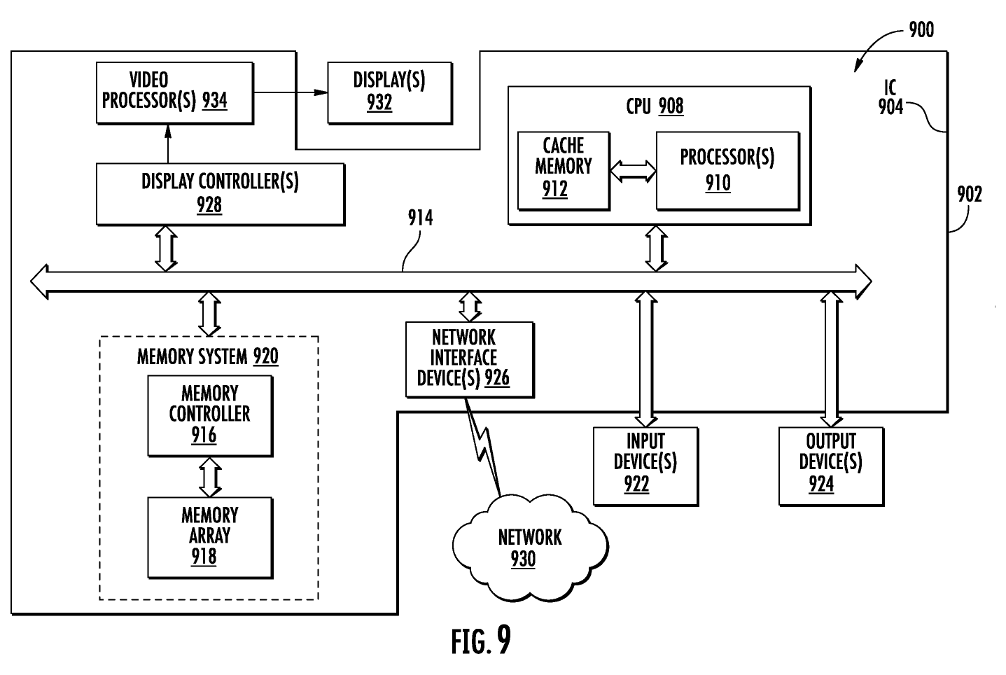

In this regard, FIG. 9 illustrates an example of a processor-based system 900 that can include microacoustic filters 400 and 700 having TCF compensation layers bilaterally disposed on their piezoelectric layers 404 and 704 to reduce spurious modes, as shown in FIGS. 4A, 4B, and 7. The processor-based system 900 includes a central processing unit (CPU) 908 that includes one or more processors 910, which may also be referred to as CPU cores or processor cores. The CPU 908 may have cache memory 912 coupled to the CPU 908 for rapid access to temporarily stored data. The CPU 908 is coupled to a system bus 914 and can intercouple master and slave devices included in the processor-based system 900. As is well known, the CPU 908 communicates with these other devices by exchanging address, control, and data information over the system bus 914. For example, the CPU 908 can communicate bus transaction requests to a memory controller 916, as an example of a slave device. Although not illustrated in FIG. 9, multiple system buses 914 could be provided, wherein each system bus 914 constitutes a different fabric.

Other master and slave devices can be connected to the system bus 914. As illustrated in FIG. 9, these devices can include a memory system 920 that includes the memory controller 916 and a memory array(s) 918, one or more input devices 922, one or more output devices 924, one or more network interface devices 926, and one or more display controllers 928, as examples. The input device(s) 922 can include any type of input device, including, but not limited to, input keys, switches, voice processors, etc. The output device(s) 924 can include any type of output device, including, but not limited to, audio, video, other visual indicators, etc. The network interface device(s) 926 can be any device configured to allow an exchange of data to and from a network 930. The network 930 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 926 can be configured to support any type of communications protocol desired.

The CPU 908 may also be configured to access the display controller(s) 928 over the system bus 914 to control information sent to one or more displays 932. The display controller(s) 928 sends information to the display(s) 932 to be displayed via one or more video processor(s) 934, which processes the information to be displayed into a format suitable for the display(s) 932. The display(s) 932 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from and write information to the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses:

1. A microacoustic filter comprising:

a piezoelectric layer having a crystalline structure operative to laterally excite a plate mode;

an electrode structure disposed adjacent a first surface of the piezoelectric layer;

a first temperature coefficient of frequency (TCF) compensation layer disposed on the first surface of the piezoelectric layer between the electrode structure and the piezoelectric layer; and

a second TCF compensation layer disposed on a second surface of the piezoelectric layer opposite to the first surface.

2. The microacoustic filter of clause 1, further comprising a substrate, wherein the electrode structure is between the substrate and the first TCF compensation layer.

3. The microacoustic filter of clause 2, further comprising a dielectric under-layer disposed between the electrode structure and the substrate.

4. The microacoustic filter of clause 3, further comprising an interstitial dielectric material, wherein:

the electrode structure comprises electrode fingers disposed on the dielectric under-layer and extending in a first direction; and

the interstitial dielectric material is disposed on the dielectric under-layer between the electrode fingers in a second direction orthogonal to the first direction.

5. The microacoustic filter of clause 4, wherein:

the first direction is parallel to the first surface of the piezoelectric layer; and

each of the interstitial dielectric material and the electrode fingers have a first thickness orthogonal to the first surface of the piezoelectric layer.

6. The microacoustic filter of any one of clause 1 to clause 5, further comprising a first passivation layer disposed on the second TCF compensation layer.

7. The microacoustic filter of clause 6, further comprising a second passivation layer disposed on the first TCF compensation layer.

8. The microacoustic filter of clause 7, wherein:

the first passivation layer and the second passivation layer each comprise a layer of silicon nitride (Si₃N₄).

9. The microacoustic filter of any one of clause 1 to clause 8, wherein the first TCF compensation layer and the second TCF compensation layer each comprise a layer of carbon-doped silicon dioxide (SiO₂C).

10. The microacoustic filter of any one of clause 1 to clause 9, wherein:

the first TCF compensation layer has a thickness orthogonal to the first surface of the piezoelectric layer in a range of five (5) to forty (40) nanometers (nm).

11. The microacoustic filter of any one of clause 1 to clause 10, further comprising a cavity between the first TCF compensation layer and the electrode structure.

12. The microacoustic filter of clause 11, wherein:

the cavity is at least partially filled with a gas; and

the gas comprises air.

13. The microacoustic filter of clause 11, wherein:

the electrode structure comprises a second surface that faces the first surface of the piezoelectric layer; and

the cavity is between the first surface of the piezoelectric layer and the second surface of the electrode structure.

14. The microacoustic filter of any one of clause 4 to clause 13, wherein:

the first direction of the electrode fingers of the electrode structure is parallel to a second axis that is perpendicular to a first axis;

a third axis is perpendicular to the first axis and the second axis;

an orientation of the first axis, the second axis, and the third axis is relative to the crystalline structure of the piezoelectric layer as defined by Euler angles lambda, mu, and theta; and

the piezoelectric layer comprises lithium niobate with the Euler angle lambda being approximately 0°, the Euler angle mu being approximately 32.5°, and the Euler angle theta being approximately 0°, or at least one symmetrical equivalent thereof.

15. The microacoustic filter of any one of clause 1 to clause 14 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

16. A method of a manufacturing a microacoustic filter, the method comprising

forming a piezoelectric layer having a crystalline structure operative to laterally excite a plate mode;

forming a first temperature coefficient of frequency (TCF) compensation layer on a first surface of the piezoelectric layer;

forming a second TCF compensation layer on a second surface of the piezoelectric layer opposite to the first surface; and

forming an electrode structure adjacent to the first surface of the piezoelectric layer.

17. The method of clause 16, wherein:

forming the electrode structure further comprises forming the electrode structure on a substrate and between the substrate and the first TCF compensation layer.

18. The method of clause 17, further comprising:

forming a dielectric under-layer between the electrode structure and the substrate;

forming the electrode structure comprising electrode fingers disposed on the dielectric under-layer and extending in a first direction; and

forming an interstitial dielectric material on the dielectric under-layer between the electrode fingers in a second direction orthogonal to the first direction.

19. The method of any one of clause 16 to clause 21, further comprising forming a cavity between the first TCF compensation layer and the electrode structure.

20. A microacoustic filter comprising:

a piezoelectric layer having a crystalline structure operative to laterally excite a plate mode;

a first dielectric layer disposed on a first surface of the piezoelectric layer;

a second dielectric layer disposed on a second surface of the piezoelectric layer opposite to the first surface; and

an electrode structure disposed on a carrier stack and spaced from the piezoelectric layer by a gap.

What is claimed is:

1. A microacoustic filter comprising:
a piezoelectric layer having a crystalline structure operative to laterally excite a plate mode;
an electrode structure disposed adjacent a first surface of the piezoelectric layer;
a first temperature coefficient of frequency (TCF) compensation layer disposed on the first surface of the piezoelectric layer between the electrode structure and the piezoelectric layer; and
a second TCF compensation layer disposed on a second surface of the piezoelectric layer opposite to the first surface.

2. The microacoustic filter of claim 1, further comprising a substrate, wherein the electrode structure is between the substrate and the first TCF compensation layer.

3. The microacoustic filter of claim 2, further comprising a dielectric under-layer disposed between the electrode structure and the substrate.

4. The microacoustic filter of claim 3, further comprising an interstitial dielectric material, wherein:
the electrode structure comprises electrode fingers disposed on the dielectric under-layer and extending in a first direction; and
the interstitial dielectric material is disposed on the dielectric under-layer between the electrode fingers in a second direction orthogonal to the first direction.

5. The microacoustic filter of claim 4, wherein:
the first direction is parallel to the first surface of the piezoelectric layer; and
each of the interstitial dielectric material and the electrode fingers have a first thickness orthogonal to the first surface of the piezoelectric layer.

6. The microacoustic filter of claim 1, further comprising a first passivation layer disposed on the second TCF compensation layer.

7. The microacoustic filter of claim 6, further comprising a second passivation layer disposed on the first TCF compensation layer.

8. The microacoustic filter of claim 7, wherein:
the first passivation layer and the second passivation layer each comprise a layer of silicon nitride (Si₃N₄).

9. The microacoustic filter of claim 1, wherein:
the first TCF compensation layer and the second TCF compensation layer each comprise a layer of carbon-doped silicon dioxide (SiO₂C).

10. The microacoustic filter of claim 1, wherein:
the first TCF compensation layer has a thickness orthogonal to the first surface of the piezoelectric layer in a range of five (5) to forty (40) nanometers (nm).

11. The microacoustic filter of claim 1, further comprising a cavity formed between the first TCF compensation layer and the electrode structure.

12. The microacoustic filter of claim 11, wherein:
the cavity is at least partially filled with a gas; or
the gas comprises air.

13. The microacoustic filter of claim 11, wherein:
the electrode structure comprises a second surface that faces the first surface of the piezoelectric layer; and
the cavity is between the first surface of the piezoelectric layer and the second surface of the electrode structure.

14. The microacoustic filter of claim 4, wherein:
the first direction of the electrode fingers of the electrode structure is parallel to a second axis that is perpendicular to a first axis;
a third axis is perpendicular to the first axis and the second axis;
an orientation of the first axis, the second axis, and the third axis is relative to the crystalline structure of the piezoelectric layer as defined by Euler angles lambda, mu, and theta; and
the piezoelectric layer comprises lithium niobate with the Euler angle lambda being approximately 0°, the Euler angle mu being approximately 32.5°, and the Euler angle theta being approximately 0°, or at least one symmetrical equivalent thereof.

15. The microacoustic filter of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

16. A method of manufacturing a microacoustic filter, the method comprising
forming a piezoelectric layer having a crystalline structure operative to laterally excite a plate mode;
forming a first temperature coefficient of frequency (TCF) compensation layer on a first surface of the piezoelectric layer;
forming a second TCF compensation layer on a second surface of the piezoelectric layer opposite to the first surface; and
forming an electrode structure adjacent to the first surface of the piezoelectric layer.

17. The method of claim 16, wherein:
forming the electrode structure further comprises forming the electrode structure on a substrate and between the substrate and the first TCF compensation layer.

18. The method of claim 17, further comprising:
forming a dielectric under-layer between the electrode structure and the substrate;
forming the electrode structure comprising electrode fingers disposed on the dielectric under-layer and extending in a first direction; and
forming an interstitial dielectric material on the dielectric under-layer between the electrode fingers in a second direction orthogonal to the first direction.

19. The method of claim 16, further comprising forming a cavity between the first TCF compensation layer and the electrode structure.

20. A microacoustic filter comprising:
a piezoelectric layer having a crystalline structure operative to laterally excite a plate mode;
a first dielectric layer disposed on a first surface of the piezoelectric layer;
a second dielectric layer disposed on a second surface of the piezoelectric layer opposite to the first surface; and
an electrode structure disposed on a carrier stack and spaced from the piezoelectric layer by a gap.
